(19) United States
(12) Patent Application Publication
(10) Pub. No.: US 2026/0371887 A1
(43) Pub. Date: Nov. 19, 2026

(54) DISPLAY APPARATUS, METHOD OF MANUFACTURING SAME, AND ELECTRONIC APPARATUS INCLUDING SAME

(71) Applicant: Samsung Display Co., Ltd., Yongin-si (KR)

(72) Inventor: YOOLGUK KIM, Yongin-si (KR)

(73) Assignee: Samsung Display Co., Ltd., Yongin-si (KR)

(21) Appl. No.: 19/639,711

(22) Filed: Apr. 6, 2026

(30) Foreign Application Priority Data
May 13, 2025 (KR) 10-2025-0062155

(51) Int. Cl. H10K 59/38; H10K 59/12; H10K 59/35; H10K 102/00

(52) U.S. Cl. CPC H10K 59/38; H10K 59/1201; H10K 59/35; H10K 2102/351

(57) ABSTRACT

Provided is a display apparatus including a substrate including a first subpixel area and a second subpixel area, a light-emitting element structure including a first light-emitting element on the substrate in the first subpixel area and a second light-emitting element on the substrate in the second subpixel area, a color filter structure including a first color filter on the first light-emitting element and a second color filter on the second light-emitting element, and a functional layer between the light-emitting element structure and the color filter structure, wherein an upper surface of the first color filter may be lower than an upper surface of the second color filter.

### CROSS-REFERENCE TO RELATED APPLICATION

This application is based on and claims priority under 35 U.S.C. § 119 to Korean Patent Application No. 10-2025-0062155, filed on May 13, 2025, in the Korean Intellectual Property Office, the disclosure of which is incorporated by reference herein in its entirety.

### BACKGROUND

### Field

The disclosure relates to a display apparatus, a method of manufacturing the display apparatus, and an electronic apparatus including the display apparatus.

### Description of the Related Art

With the evolution of various electronic devices, such as mobile phones, personal digital assistants (PDAs), computers, and large televisions (TVs), various types of display apparatuses applicable to these devices have been developed. For example, display apparatuses widely used in the market include liquid crystal display apparatuses including backlight units, and organic light-emitting display apparatuses which emit different colors of light for respective display areas.

Recently, to reduce costs and improve luminous efficiency, polarizing layers have been removed and color filters have been introduced to display apparatuses. For example, display apparatuses have been developed in a direction which maintains luminous efficiency while simplifying the manufacturing process.

The aforementioned background technology is technical information that the inventor possessed for developing the disclosure or acquired during the development process of the disclosure, and may not be considered publicly known technology disclosed to the general public prior to the filing of the disclosure.

### SUMMARY

Provided is a display apparatus in which a black matrix between adjacent color filters in an emission unit is omitted such that integration and resolution are improved, and an electronic apparatus including the display apparatus.

The problems to be solved by the disclosure are not limited to the problems mentioned above, and other problems and advantages of the disclosure not mentioned may be understood from the following description and will be more clearly understood by the embodiments of the disclosure. It will be understood that the problems to be solved by the disclosure and the advantages of the disclosure may be realized by means and combinations thereof indicated in the patent claims.

According to an embodiment of the disclosure, a display apparatus includes a substrate including a first subpixel area and a second subpixel area, a light-emitting element structure including a first light-emitting element on the substrate in the first subpixel area and a second light-emitting element on the substrate in the second subpixel area, a color filter structure including a first color filter on the first light-emitting element and a second color filter on the second light-emitting element, and a functional layer between the light-emitting element structure and the color filter structure, wherein an upper surface of the first color filter may be lower than an upper surface of the second color filter.

In the embodiment, the light-emitting element structure may further include a third light-emitting element on the substrate in a third subpixel area, the color filter structure may further include a third color filter on the third light-emitting element, and the display apparatus may further include a first organic layer between the second color filter and the functional layer and a second organic layer between the third color filter and the functional layer.

In the embodiment, a thickness of the second organic layer may be greater than a thickness of the first organic layer.

In the embodiment, a thickness of the first color filter may be greater than the thickness of the second organic layer.

In the embodiment, a thickness of the first organic layer may be in a range of 1 μm to 3 μm.

In the embodiment, the first organic layer and the second organic layer may have liquid repellency.

In the embodiment, the first color filter and the second color filter may have liquid repellency.

In the embodiment, the first organic layer and the second organic layer may have a same thickness.

In the embodiment, the first color filter may have liquid repellency.

In the embodiment, the light-emitting element structure may include an emission unit including two first light-emitting elements, one second light-emitting element, and one third light-emitting element, in the emission unit, the second light-emitting element and the third light-emitting element may face each other, and the two first light-emitting elements may face each other in a first diagonal direction and may be between the second light-emitting element and the third light-emitting element in a second diagonal direction.

According to another embodiment of the disclosure, a method of manufacturing a display apparatus includes, on a substrate including a first subpixel area, a second subpixel area, and a third subpixel area, forming a first organic layer in the second subpixel area and a second organic layer in the third subpixel area, forming, on the substrate, a first color filter in the first subpixel area, forming a second color filter on the first organic layer, and forming a third color filter on the second organic layer, wherein an upper surface of the first color filter is lower than an upper surface of the second color filter.

In the embodiment, the method may further include, during formation of the first organic layer and the second organic layer, applying a liquid-repellent treatment to the first organic layer and the second organic layer.

In the embodiment, the method may further include, during formation of the first color filter, applying a liquid-repellent treatment to the first color filter.

In the embodiment, the method may further include, during formation of the second color filter, applying a liquid-repellent treatment to the second color filter.

In the embodiment, a thickness of the second organic layer may be greater than a thickness of the first organic layer.

In the embodiment, a thickness of the first color filter may be greater than the thickness of the second organic layer.

In the embodiment, an upper surface of the third color filter may be higher than the upper surface of the second color filter.

In the embodiment, the first organic layer and the second organic layer may have a same thickness.

In the embodiment, an upper surface of the third color filter and an upper surface of the second color filter may be at a same level.

According to another embodiment of the disclosure, an electronic apparatus includes a memory configured to store at least one program, a processor configured to execute the at least one program, a display apparatus configured to receive data from the processor and provide visual information, and a power supply configured to supply power to the display apparatus, wherein the display apparatus includes a substrate including a first subpixel area and a second subpixel area, a light-emitting element structure including a first light-emitting element on the substrate in the first subpixel area and a second light-emitting element on the substrate in the second subpixel area, a color filter structure including a first color filter on the first light-emitting element and a second color filter on the second light-emitting element, and a functional layer between the light-emitting element structure and the color filter structure, wherein an upper surface of the first color filter is lower than an upper surface of the second color filter.

### BRIEF DESCRIPTION OF DRAWINGS

The following drawings illustrate embodiments of the disclosure and, together with the detailed description, serve to further explain the technical idea of the disclosure. Thus, the disclosure should not be interpreted as being limited only to the content depicted in the drawings:

FIG. 1 is a schematic plan view of a display apparatus according to an embodiment of the disclosure;

FIG. 2 is a schematic perspective view of a bent shape of the display apparatus of FIG. 1;

FIG. 3 is a schematic block diagram of a structure of the display apparatus of FIG. 1;

FIG. 4 is a schematic diagram of an equivalent circuit of a subpixel of the display apparatus of FIG. 1;

FIG. 5 is a schematic cross-sectional view taken along line A-A’ of FIG. 1;

FIG. 6 is a schematic plan view of an emission unit of the display apparatus of FIG. 1;

FIG. 7 is a schematic cross-sectional view taken along line B-B’ of FIG. 6;

FIGS. 8, 9, 10, and 11 are schematic views illustrating a method of manufacturing the emission unit of FIG. 7;

FIG. 12 is a graph illustrating a change in contact angle according to thicknesses of a liquid-repellent material;

FIG. 13 is a graph illustrating a time-of-flight secondary ion mass spectrometry (TOF-SIMS) depth profile during a liquid-repellent plasma treatment;

FIGS. 14A and 14B are schematic views of an emission unit of the display apparatus of FIG. 1, according to another embodiment;

FIGS. 15-17 are schematic cross-sectional views illustrating a method of manufacturing the emission unit of FIGS. 14A and 14B;

FIG. 18 is a block diagram of an electronic apparatus according to an embodiment; and

FIG. 19 illustrates schematic diagrams of electronic apparatuses according to various embodiments.

### DETAILED DESCRIPTION

As various modifications may be applied and numerous embodiments may be implemented, particular embodiments will be illustrated in the drawings and described in detail in the written description. Effects and features of the disclosure, and methods for achieving them will be clarified with reference to embodiments described below in detail with reference to the drawings. However, the disclosure may take different forms and should not be construed as being limited to the descriptions set forth herein.

In the following embodiments, it will be understood that although terms “first” and “second” may be used to describe various elements, these elements should not be limited by these terms. The terms are used to distinguish an element from another.

In the following embodiments, singular forms include plural forms unless the context clearly indicates otherwise.

In the following embodiments, it will be understood that terms “comprise,” “include,” and “have” used herein specify the presence of stated features or elements, but do not preclude the presence or addition of one or more other features or elements.

In the following embodiments, it will be further understood that, when a layer, region, or element is referred to as being “on” another layer, region, or element, it may be directly or indirectly on the other layer, region, or element. For example, intervening layers, regions, or elements may be.

Sizes of elements in the drawings may be exaggerated or reduced for convenience of description. For example, because sizes and thicknesses of elements in the drawings are arbitrarily illustrated for convenience of explanation, the disclosure is not limited thereto.

Hereinafter, the embodiments of the disclosure will now be described in detail with reference to the accompanying drawings. When described with reference to the drawings, identical or corresponding elements will be given the same reference numerals, and redundant descriptions of these elements will be omitted.

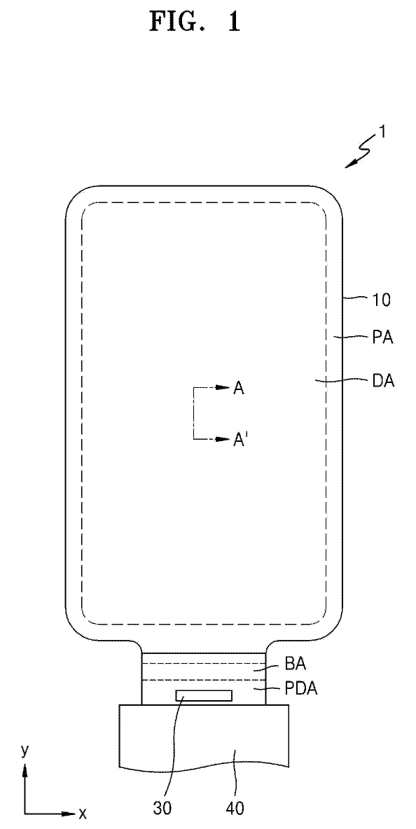

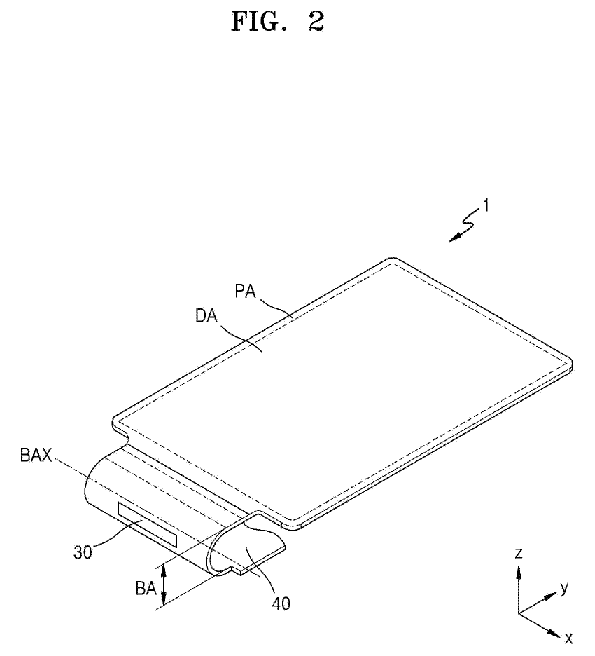

FIG. 1 is a schematic plan view of a display apparatus according to an embodiment of the disclosure, and FIG. 2 is a schematic perspective view of a bent shape of the display apparatus of FIG. 1.

In the disclosure, a “first direction x” may be a direction parallel to a width direction of a display apparatus or a bending axis BAX to be described below. A “second direction y” may be a longitudinal direction of the display apparatus 1. A “third direction z” may correspond to a stacking direction of the components of the display apparatus 1 to be described below or a direction perpendicular to both the first direction x and the second direction y, and the first direction x, the second direction y, and the third direction z may be directions perpendicular to each other.

Referring to FIGS. 1 and 2, the display apparatus 1 may display a moving image or a still image and may display a screen on a display panel 10 or perform input and output of data. The display apparatus 1 described above may be used as a display screen of various electronic apparatuses, such as a mobile phone, a smartphone, a tablet personal computer (PC), a mobile communication terminal, an electronic notebook, an electronic book, a portable multimedia player (PMP), a navigation apparatus, and an ultra-mobile PC (UMPC), as well as a television (TV), a laptop computer, a monitor, a billboard, or an Internet of Things (IoT) apparatus. According to an embodiment, the display apparatus 1 may be used in electronic apparatuses, such as wearable devices including a smartwatch, a watch phone, a glasses-type display, and a head-mounted display (HMD). For example, the display apparatus 1 according to an embodiment may be used as a display of various electronic apparatuses, for example, a center information display (CID) positioned on an instrument panel, a center fascia, or a dashboard of a vehicle, a room mirror display replacing a side-view mirror of a vehicle, and an entertainment display positioned on the back of a front seat.

The display apparatus 1 according to an embodiment of the disclosure may include a display area DA in which a plurality of pixels are positioned, and a peripheral area PA positioned outside the display area DA. For example, the peripheral area PA may include a pad area PDA, which is positioned on a side of the display area DA and is an area where various electronic components, such as an integrated circuit 30, or a flexible circuit board 40 are electrically attached, and a bending area BA between the display area DA and the pad area PDA. The display area DA, the peripheral area PA, the pad area PDA, and the bending area BA described above may be partitioned on a substrate.

FIG. 1 is a plan view illustrating the shape of a substrate during a manufacturing process of the display apparatus 1, and as illustrated in FIG. 2, the substrate may have the bending area BA bent along a bending axis BAX extending in a first direction x. For example, a bending direction may be set such that the pad area PDA may be positioned behind the display area DA. Accordingly, the area of the peripheral area PA perceived by a user may be minimized.

A circuit cover may be attached to the integrated circuit 30 and the flexible circuit board 40 of the pad area PDA. The circuit cover may protect the integrated circuit 30 and the flexible circuit board 40 from mechanical shock and may provide waterproofing and insulation performance to the integrated circuit 30 and the flexible circuit board 40.

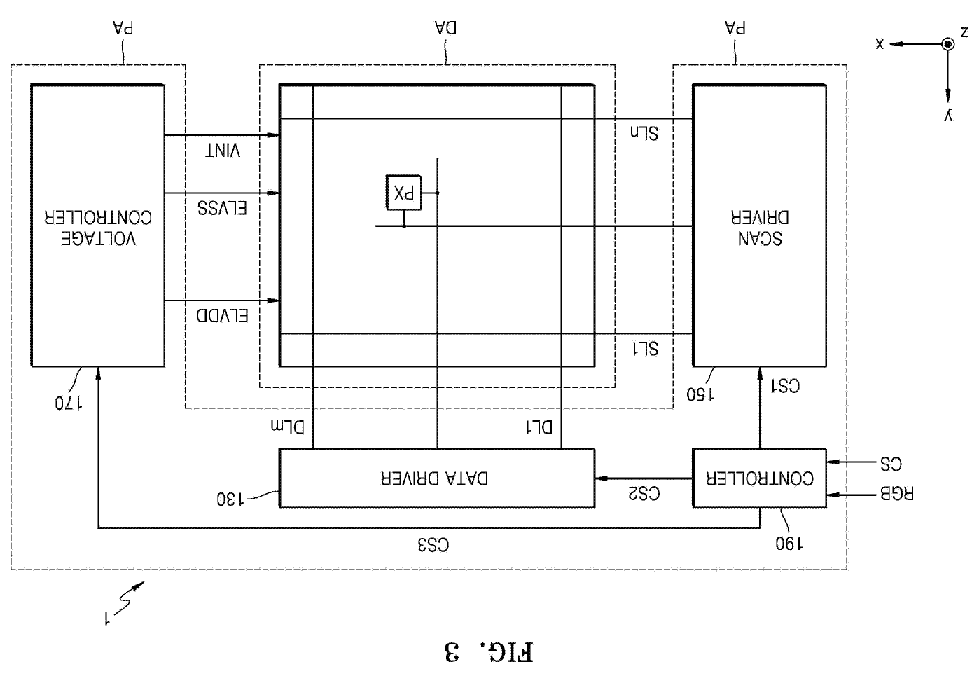

FIG. 3 is a schematic block diagram of a structure of the display apparatus of FIG. 1.

Referring to FIG. 3, a plurality of scan lines SL1, ..., and SLn extending in the first direction x, a plurality of data lines DL1, ..., and DLm extending in a second direction y perpendicular to the first direction x, and a plurality of subpixels PX may be positioned in the display area DA. Here, m and n may be each natural numbers.

Wires through which electrical signals may be applied to the plurality of subpixels PX may include the plurality of scan lines SL1, ..., and SLn, the plurality of data lines DL1, ..., and DLm, or the like. The plurality of scan lines SL1, ..., and SLn, for example, may be positioned in a plurality of rows extending in the first direction x to transmit scan signals to the subpixels PX, the plurality of data lines DL1, ..., and DLm, for example, may be positioned in a plurality of columns extending in the second direction y to transmit data signals to the subpixels PX, and the plurality of subpixels PX may be positioned at intersections of the plurality of scan lines SL1, ..., and SLn and the plurality of data lines DL1, ..., and DLm.

Each of the subpixels PX may include a light-emitting element and emit red light, green light, blue light, or white light. For example, each of the subpixels PX may include an organic light-emitting diode (OLED) as a light-emitting element, but the disclosure is not limited thereto.

A data driver 130 may provide data signals to the display area DA, a scan driver 150 may provide scan signals to the display area DA, a voltage controller 170 may control voltages supplied to the display area DA, and a controller 190 may control the data driver 130, the scan driver 150, and the voltage controller 170. For example, the data driver 130, the scan driver 150, the voltage controller 170, and the controller 190 may be positioned in the peripheral area PA.

The voltage controller 170 may generate and control a first voltage ELVDD, a second voltage ELVSS, and an initialization voltage VINT provided to the display area DA.

The first voltage ELVDD, the second voltage ELVSS, and the initialization voltage VINT may be applied to the plurality of subpixels PX. For example, the first voltage ELVDD may be a positive voltage, and the second voltage ELVSS may be a negative voltage or a ground voltage. For example, the second voltage ELVSS may have a lower level than the first voltage ELVDD.

The controller 190 may receive image signals RGB and a control signal CS from an external source (e.g., a system board). The controller 190 may generate image data by converting the data format of the image signals RGB to match interface specifications with the data driver 130. The controller 190 may provide, to the data driver 130, the converted image data.

The controller 190 may generate and output a first control signal CS1, a second control signal CS2, and a third control signal CS3 in response to the control signal CS provided from the external source. The first control signal CS1 may be referred to as a scan control signal. The second control signal CS2 may be referred to as a data control signal. The third control signal CS3 may be referred to as a voltage control signal. The first control signal CS1 may be provided to the scan driver 150. For example, the second control signal CS2 may be provided to the data driver 130, and the third control signal CS3 may be provided to the voltage controller 170.

The scan driver 150 may generate a plurality of scan signals in response to the first control signal CS1. The plurality of scan signals may be applied to the plurality of subpixels PX through the plurality of scan lines SL1, ..., and SLn.

The data driver 130 may generate a plurality of data voltages corresponding to the image data in response to the second control signal CS2. The plurality of data voltages may be applied to the plurality of subpixels PX through the data lines DL1, ..., and DLm. The data driver 130 may simultaneously provide, to the data lines DL1, ..., and DLm, the data voltages generated in units of subpixel rows for the plurality of subpixels PX.

The plurality of subpixels PX may receive the plurality of data voltages in response to the plurality of scan signals. The plurality of subpixels PX may display an image by emitting light having a luminance corresponding to the plurality of data voltages. The plurality of subpixels PX may display the image by emitting light sequentially or simultaneously.

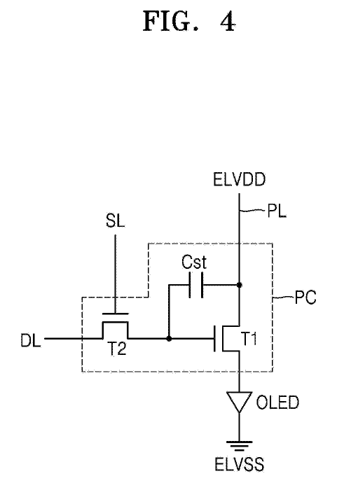

FIG. 4 is a schematic diagram of an equivalent circuit of a subpixel of the display apparatus of FIG. 1.

Referring to FIG. 4, a pixel circuit PC may be connected to a display element, for example, an organic light-emitting diode OLED. The pixel circuit PC may be positioned in the display area DA. The pixel circuit PC may include a driving thin-film transistor T1, a switching thin-film transistor T2, and a storage capacitor Cst. For example, the organic light-emitting diode OLED may emit red light, green light, or blue light, or may emit red light, green light, blue light, or white light.

The switching thin-film transistor T2 may be connected to a scan line SL and a data line DL and may transmit a data signal or a data voltage input from the data line DL to the driving thin-film transistor T1 based on a scan signal or a switching voltage input from the scan line SL. The storage capacitor Cst may be connected to the switching thin-film transistor T2 and a driving voltage line PL and may store a voltage corresponding to the difference between a voltage received from the switching thin-film transistor T2 and the first voltage ELVDD supplied to the driving voltage line PL.

The driving thin-film transistor T1 may be connected to the driving voltage line PL and the storage capacitor Cst and may control a driving current flowing from the driving voltage line PL to the organic light-emitting diode OLED in response to a voltage value stored in the storage capacitor Cst. The organic light-emitting diode OLED may emit light having a certain luminance according to the driving current. An opposite electrode of the organic light-emitting diode OLED may receive the second voltage ELVSS.

FIG. 4 illustrates that the pixel circuit PC includes two thin-film transistors and one storage capacitor, but the pixel circuit PC may include three or more thin-film transistors, and the pixel circuit PC may include two or more capacitors.

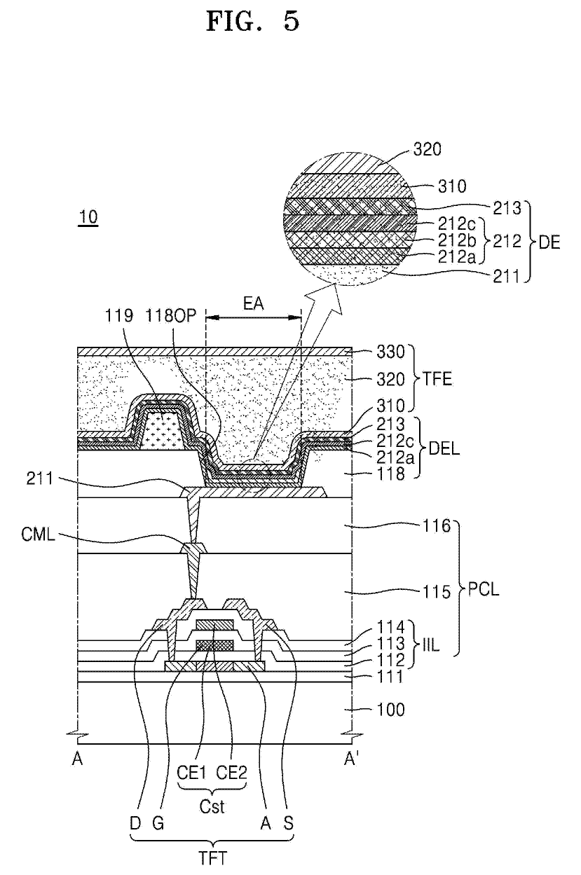

FIG. 5 is a schematic cross-sectional view taken along line A-A’ of FIG. 1.

Referring to FIG. 5, the display apparatus 1 may include the display panel 10. For example, the display panel 10 may include a substrate 100, a buffer layer 111, a pixel circuit layer PCL, a display element layer DEL, and a thin-film encapsulation layer TFE.

The substrate 100 may include a transparent glass material having silicon dioxide (SiO₂) as a main component. However, the disclosure is not limited thereto, and, in another example, the substrate 100 may include a transparent plastic material. The transparent plastic material may include polyethersulfone (PES), polyacrylate (PAR), polyetherimide (PEI), polyethylene naphthenate (PEN), polyethylene terephthalate (PET), polyphenylene sulfide (PPS), polyarylate, polyimide, polycarbonate (PC), cellulose triacetate (TAC), cellulose acetate propionate (CAP), or the like. In an embodiment, the substrate 100 may have a multilayer structure including a base layer including the aforementioned plastic, and a barrier layer. The substrate 100 including plastic may be flexible, rollable, and bendable.

The buffer layer 111 may be positioned on the substrate 100. The buffer layer 111 may include an inorganic insulating material, such as silicon nitride (SiNₓ), silicon oxynitride (SiOₓN_{y}), or silicon dioxide (SiO₂), and may be formed as a single layer or a multilayer including the aforementioned inorganic insulating materials.

The pixel circuit layer PCL may be positioned on the buffer layer 111. The pixel circuit layer PCL may include a thin-film transistor TFT included in a pixel circuit and an inorganic insulating layer IIL, a first planarization layer 115, and a second planarization layer 116 positioned below and/or over the components of the thin-film transistor TFT. The inorganic insulating layer IIL may include a first gate insulating layer 112, a second gate insulating layer 113, and an interlayer insulating layer 114.

The thin-film transistor TFT of FIG. 5 may include either one of the driving thin-film transistor T1 or the switching thin-film transistor T2 shown in and described with reference to FIG. 4. However, the disclosure is not limited thereto, and, in another example, the thin-film transistor TFT of FIG. 5 may include various transistors including, for example, an initialization transistor.

The thin-film transistor TFT may include a semiconductor layer A, and the semiconductor layer A may include polysilicon. In another example, the semiconductor layer A may include amorphous silicon, an oxide semiconductor, or an organic semiconductor. The semiconductor layer A may include a channel region and a drain region and a source region positioned on respective sides of the channel region. A gate electrode G may overlap the channel region.

The gate electrode G may include a low-resistance metal material. The gate electrode G may include a conductive material including molybdenum (Mo), aluminum (Al), copper (Cu), titanium (Ti), or the like, and may be formed as a multilayer or a single layer including the aforementioned conductive materials.

The first gate insulating layer 112 between the semiconductor layer A and the gate electrode G may include an inorganic insulating material, such as silicon dioxide (SiO₂), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), or zinc oxide (ZnOₓ). ZnOₓ may include ZnO and/or ZnO₂.

The second gate insulating layer 113 may cover the gate electrode G. The second gate insulating layer 113 may include an inorganic insulating material, such as SiO₂, SiNₓ, SiOₓN_{y}, Al₂O₃, TiO₂, Ta₂O₅, HfO₂, or ZnOₓ, similar to the first gate insulating layer 112. ZnOₓ may include ZnO and/or ZnO₂.

An upper electrode CE2 of the storage capacitor Cst may be positioned on the second gate insulating layer 113. The upper electrode CE2 may overlap the gate electrode G positioned below the upper electrode CE2. For example, the gate electrode G and the upper electrode CE2 overlapping each other with the second gate insulating layer 113 may form the storage capacitor Cst of the pixel circuit, the second gate insulating layer 113 being positioned between the gate electrode G and the upper electrode CE2. For example, the gate electrode G may function as a lower electrode CE1 of the storage capacitor Cst. As described above, the storage capacitor Cst and the thin-film transistor TFT may overlap each other. However, the disclosure is not limited thereto, and in some embodiments, the storage capacitor Cst may not overlap the thin-film transistor TFT.

The upper electrode CE2 may include one or more of Al, platinum (Pt), palladium (Pd), silver (Ag), magnesium (Mg), gold (Au), nickel (Ni), neodymium (Nd), iridium (Ir), chromium (Cr), calcium (Ca), Mo, Ti, tungsten (W), and/or Cu, and may be formed as a single layer or a multilayer of the aforementioned materials.

The interlayer insulating layer 114 may cover the upper electrode CE2. The interlayer insulating layer 114 may include SiO₂, SiNₓ, SiOₓN_{y}, Al₂O₃, TiO₂, Ta₂O₅, HfO₂, or ZnOₓ. ZnOₓ may include ZnO and/or ZnO₂. The interlayer insulating layer 114 may be formed as a single layer or a multilayer including the aforementioned inorganic insulating materials.

Each of a drain electrode D and a source electrode S may be positioned on the interlayer insulating layer 114. The drain electrode D and the source electrode S may each include a material having good conductivity. The drain electrode D and the source electrode S may each include a conductive material including Mo, Al, Cu, Ti, or the like, and may be formed as a multilayer or a single layer including the aforementioned conductive materials. As an example, the drain electrode D and the source electrode S may each have a multilayer structure of Ti/Al/Ti.

The first planarization layer 115 may cover the drain electrode D and the source electrode S. The first planarization layer 115 may include an organic insulating layer. The first planarization layer 115 may include an organic insulator, such as a general-purpose polymer including polymethyl methacrylate (PMMA) or polystyrene (PS), a polymer derivative having a phenol-based group, an acrylic polymer, an imide-based polymer, an aryl ether-based polymer, an amide-based polymer, a fluorine-based polymer, a p-xylene-based polymer, a vinyl alcohol-based polymer, or blends thereof.

A connection electrode CML may be positioned on the first planarization layer 115. For example, the connection electrode CML may be connected to the drain electrode D or the source electrode S through a contact hole of the first planarization layer 115. The connection electrode CML may include a material having good conductivity. The connection electrode CML may include a conductive material including Mo, Al, Cu, Ti, or the like, and may be formed as a multilayer or a single layer including the aforementioned conductive materials. In an embodiment, the connection electrode CML may have a multilayer structure of Ti/Al/Ti. In another embodiment, the connection electrode CML may be omitted.

The second planarization layer 116 may cover the connection electrode CML. The second planarization layer 116 may include an organic insulating layer. The second planarization layer 116 may include an organic insulator, such as a general-purpose polymer including PMMA or PS, a polymer derivative having a phenol-based group, an acrylic polymer, an imide-based polymer, an aryl ether-based polymer, an amide-based polymer, a fluorine-based polymer, a p-xylene-based polymer, a vinyl alcohol-based polymer, or blends thereof.

The display element layer DEL may be positioned on the pixel circuit layer PCL, and may include a display element DE. For example, the display element DE may include an organic light-emitting diode OLED, which is a light-emitting element. A pixel electrode 211 of the display element DE may be electrically connected to the connection electrode CML through a contact hole of the second planarization layer 116. For example, the display element DE may include a light-emitting element. The light-emitting element may include the pixel electrode 211, an intermediate layer 212, and an opposite electrode 213.

The pixel electrode 211 may include a conductive oxide material, such as indium tin oxide (ITO), indium zinc oxide (IZO), zinc oxide (ZnO), indium oxide (In₂O₃), indium gallium oxide (IGO), or aluminum zinc oxide (AZO). In another embodiment, the pixel electrode 211 may include a reflective layer including Ag, Mg, Al, Pt, Pd, Au, Ni, Nd, Ir, Cr, or compounds thereof. In another embodiment, the pixel electrode 211 may further include a layer, which is over/below the reflective layer and includes ITO, IZO, ZnO, or In₂O₃.

A pixel-defining layer 118 including an opening 118OPwhich exposes a central portion of the pixel electrode 211 may be positioned on the pixel electrode 211. The pixel-defining layer 118 may include an organic insulating material and/or an inorganic insulating material. The opening 118OP may be provided in an emission area (hereinafter referred to as the emission area EA) where light is emitted from the display element DE. For example, a width of the opening 118OP may correspond to a width of the emission area EA of the display element DE.

In an embodiment, the pixel-defining layer 118 may include a light-blocking material and may be provided in black. The light-blocking material may include carbon black, carbon nanotubes, resin or paste including black dye, metal particles, for example, Ni, Al, Mo, or alloys thereof, metal oxide particles (e.g., chromium oxide), or metal nitride particles (e.g., chromium nitride). In case that the pixel-defining layer 118 includes a light-blocking material, the pixel-defining layer 118 may reduce external light reflection caused by metal structures positioned below the pixel-defining layer 118.

A spacer 119 may be positioned on the pixel-defining layer 118. The spacer 119 may prevent damage to the substrate 100 in a method of manufacturing the display apparatus. A mask sheet may be used to manufacture the display panel 10. The mask sheet may prevent defects (e.g., damage or breakage of a portion of the substrate 100) when the mask sheet enters the opening 118OP of the pixel-defining layer 118 or adheres to the pixel-defining layer 118 during deposition of a deposition material on the substrate 100.

The spacer 119 may include an organic insulator, such as polyimide. In another embodiment, the spacer 119 may include an inorganic insulating material, such as silicon nitride or silicon oxide, or may include both an organic insulating material and an inorganic insulating material.

In an embodiment, the spacer 119 may include a different material from the material of the pixel-defining layer 118. In another embodiment, the spacer 119 and the pixel-defining layer 118 may include a same material, and the pixel-defining layer 118 and the spacer 119 may be formed together in a mask process using a halftone mask or the like.

The intermediate layer 212 may be positioned on the pixel-defining layer 118. The intermediate layer 212 may include an emission layer 212b positioned in the opening 118OP of the pixel-defining layer 118. The emission layer 212b may include a polymer or low-molecular-weight organic material which emits light of a certain color.

A first charge control layer 212a and a second charge control layer 212c may be positioned below and over the emission layer 212b, respectively. The first charge control layer 212a may include, for example, a hole transport layer (HTL), or may include a hole transport layer and a hole injection layer (HIL). The second charge control layer 212c, as a component positioned on the emission layer 212b, may be optional. The second charge control layer 212c may include an electron transport layer (ETL) and/or an electron injection layer (EIL). The first charge control layer 212a and/or the second charge control layer 212c may be a common layer formed to cover the entire substrate 100, like the opposite electrode 213 to be described below.

The opposite electrode 213 may include a conductive material having a low work function. For example, the opposite electrode 213 may include a semi-transparent layer or a transparent layer including Ag, Mg, Al, Pt, Pd, Au, Ni, Nd, Ir, Cr, lithium (Li), Ca, or alloys thereof. In another embodiment, the opposite electrode 213 may further include a layer, such as ITO, IZO, ZnO, or In₂O₃, on the semi-transparent layer or the transparent layer including the aforementioned materials.

In some embodiments, a capping layer may be further positioned over the opposite electrode 213. The capping layer may include lithium fluoride (LiF), an inorganic material, and/or an organic material.

The thin-film encapsulation layer TFE may be positioned on the opposite electrode 213. In an embodiment, the thin-film encapsulation layer TFE may include at least one inorganic encapsulation layer and at least one organic encapsulation layer. For example, the thin-film encapsulation layer TFE may include a first inorganic encapsulation layer 310, an organic encapsulation layer 320, and a second inorganic encapsulation layer 330, which are sequentially stacked.

The first inorganic encapsulation layer 310 and the second inorganic encapsulation layer 330 may each include one or more inorganic materials among aluminum oxide, titanium oxide, tantalum oxide, hafnium oxide, zinc oxide, silicon oxide, silicon nitride, and silicon oxynitride. The organic encapsulation layer 320 may include a polymer-based material. The polymer-based material may include acrylic resin, epoxy resin, polyimide, polyethylene, or the like. In an embodiment, the organic encapsulation layer 320 may include acrylate.

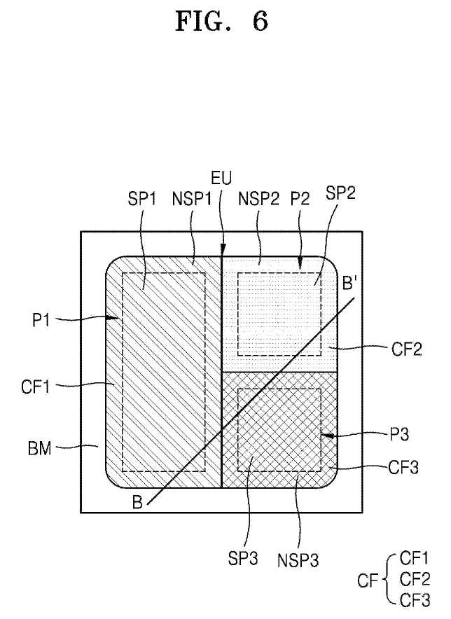

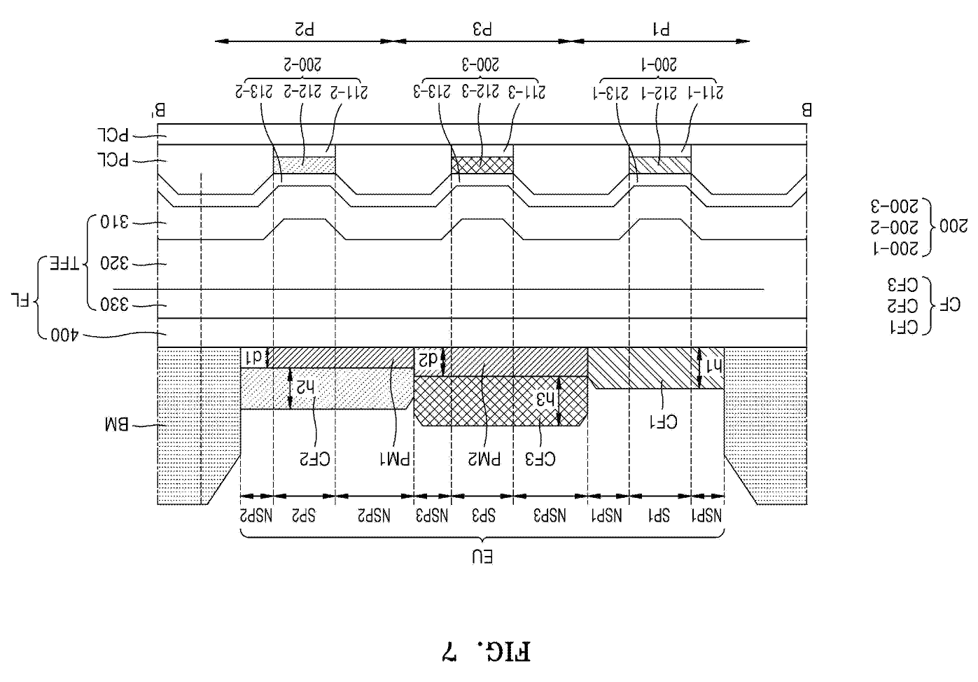

FIG. 6 is a schematic plan view of an emission unit of the display apparatus of FIGS. 1, and 7 is a schematic cross-sectional view taken along line B-B’ of FIG. 6.

Referring to FIGS. 6 and 7 together with FIG. 5, the display apparatus according to an embodiment of the disclosure may include the substrate 100 including at least a first subpixel area P1, a second subpixel area P2, and a third subpixel area P3, a light-emitting element structure 200 including a first light-emitting element 200-1 positioned on the substrate 100 in the first subpixel area P1, a second light-emitting element 200-2 positioned on the substrate 100 in the second subpixel area P2, and a third light-emitting element 200-3 positioned on the substrate 100 in the third subpixel area P3, a color filter structure CF including a first color filter CF1 on the first light-emitting element 200-1, a second color filter CF2 on the second light-emitting element 200-2, and a third color filter CF3 on the third light-emitting element 200-3, and a functional layer FL between the light-emitting element structure 200 and the color filter structure CF.

The “light-emitting element” shown in and described with reference to FIG. 5 may refer to any one of the first light-emitting element 200-1, the second light-emitting element 200-2, or the third light-emitting element 200-3 of the light-emitting element structure 200. For example, the first light-emitting element 200-1 may include a first pixel electrode 211-1, a first intermediate layer 212-1, and a first opposite electrode 213-1, which are sequentially stacked. For example, the second light-emitting element 200-2 may include a second pixel electrode 211-2, a second intermediate layer 212-2, and a second opposite electrode 213-2, which are sequentially stacked. The third light-emitting element 200-3 may include a third pixel electrode 211-3, a third intermediate layer 212-3, and a third opposite electrode 213-3, which are sequentially stacked.

The first intermediate layer 212-1, the second intermediate layer 212-2, and the third intermediate layer 212-3 may each include an emission layer 212b (see FIG. 5) which emits a different color. For example, the first intermediate layer 212-1 may emit blue light due to a voltage difference between the first pixel electrode 211-1 and the first opposite electrode 213-1, the second intermediate layer 212-2 may emit red light due to a voltage difference between the second pixel electrode 211-2 and the second opposite electrode 213-2, and the third intermediate layer 212-3 may emit green light due to a voltage difference between the third pixel electrode 211-3 and the third opposite electrode 213-3.

The first opposite electrode 213-1, the second opposite electrode 213-2, and the third opposite electrode 213-3 may be portions of a common layer having a same potential. For example, the first opposite electrode 213-1, the second opposite electrode 213-2, and the third opposite electrode 213-3 may each refer to a portion of the opposite electrode 213 (see FIG. 5) positioned in a same layer.

In some embodiments, the first color filter CF1 may transmit light of a same wavelength as light emitted from the first light-emitting element 200-1. For example, the second color filter CF2 may transmit light of a same wavelength as light emitted from the second light-emitting element 200-2. For example, the third color filter CF3 may transmit light of a same wavelength as light emitted from the third light-emitting element 200-3.

A width of the first color filter CF1 of the color filter structure CF may be greater than a width of the first intermediate layer 212-1 of the first light-emitting element 200-1 positioned in the first subpixel area P1. The first color filter CF1 may include an overlapping portion SP1 which overlaps the first intermediate layer 212-1 in the first subpixel area P1 and a non-overlapping portion NSP1 which does not overlap the first intermediate layer 212-1 in the first subpixel area P1.

For example, a width of the second color filter CF2 of the color filter structure CF may be greater than a width of the second intermediate layer 212-2 of the second light-emitting element 200-2 positioned in the second subpixel area P2. The second color filter CF2 may include an overlapping portion SP2 which overlaps the second intermediate layer 212-2 in the second subpixel area P2 and a non-overlapping portion NSP2 which does not overlap the second intermediate layer 212-2 in the second subpixel area P2.

For example, a width of the third color filter CF3 of the color filter structure CF may be greater than a width of the third intermediate layer 212-3 of the third light-emitting element 200-3 positioned in the third subpixel area P3. The third color filter CF3 may include an overlapping portion SP3 which overlaps the third intermediate layer 212-3 in the third subpixel area P3 and a non-overlapping portion NSP3 which does not overlap the third intermediate layer 212-3 in the third subpixel area P3.

In the disclosure, the widths of the first, second, and third color filters CF1, CF2, and CF3 and the widths of the first, second, and third intermediate layers 212-1, 212-2, and 212-3 may be lengths measured in a direction perpendicular to the third direction z (see FIG. 1), which is a stacking direction of the components of the display apparatus 1 (see FIG. 1).

In some embodiments, the functional layer FL positioned between the light-emitting element structure 200 and the color filter structure CF may include the thin-film encapsulation layer TFE and an input sensing layer 400. The explanation of the thin-film encapsulation layer TFE is omitted as described with reference to FIG. 5. The functional layer FL may further include, for example, an anti-reflection layer and layers having various functions on or over the input sensing layer 400.

The input sensing layer 400 may obtain coordinate information according to an external input, for example, a touch event. The input sensing layer 400 may include sensing electrodes (or touch electrodes) and trace lines connected to the sensing electrodes. The input sensing layer 400 may be positioned on the thin-film encapsulation layer TFE. The input sensing layer 4layer 400nse an external input by using a mutual capacitance method and/or a self-capacitance method.

The input sensing layer 400 may be formed (e.g., directly formed) on the thin-film encapsulation layer TFE, or may be formed separately and then combined (or laminated) by an adhesive layer, such as an optically transparent adhesive or an optically clear adhesive (OCA). For example, a process of forming the input sensing layer 400 may be carried out continuously after a process of forming the thin-film encapsulation layer TFE, and an adhesive layer may not be positioned between the input sensing layer 400 and the thin-film encapsulation layer TFE.

The first color filter CF1 positioned in the first subpixel area P1, the second color filter CF2 positioned in the second subpixel area P2, and the third color filter CF3 positioned in the third subpixel area P3 may be positioned over the functional layer FL.

The display apparatus 1 according to an embodiment of the disclosure may further include a first organic layer PM1 positioned between the second color filter CF2 and the functional layer FL, and a second organic layer PM2 positioned between the third color filter CF3 and the functional layer FL. For example, the first color filter CF1 may be positioned (e.g., positioned directly) on the functional layer FL, the second color filter CF2 may be positioned on the first organic layer PM1 on the functional layer FL, and the third color filter CF3 may be positioned on the second organic layer PM2 on the functional layer FL. For example, a thickness d2 of the second organic layer PM2 may be greater than a thickness d1 of the first organic layer Player PM1.

For example, steps may be formed between the first color filter CF1, the second color filter CF2, and the third color filter CF3, respectively. For example, an upper surface of the first color filter CF1 may be positioned lower than an upper surface of the second color filter CF2, and the upper surface of the second color filter CF2 may be positioned lower than an upper surface of the third color filter CF3.

In the disclosure, the thickness d1 of the first organic layer PM1 and the thickness d2 of the second organic layer PM2 may be distances measured in the third direction z, which is the stacking direction of the display apparatus 1.

In the disclosure, the expression “the upper surface of the first color filter CF1 is positioned lower than the upper surface of the second color filter CF2” may mean that the upper surface of the first color filter CF1 is positioned lower than the upper surface of the second color filter CF2 with reference to the substrate 100. For example, a distance between the substrate 100 and the upper surface of the first color filter CF1 measured in the third direction z may be less than a distance between the substrate 100 and the upper surface of the second color filter CF2 measured in the third direction z.

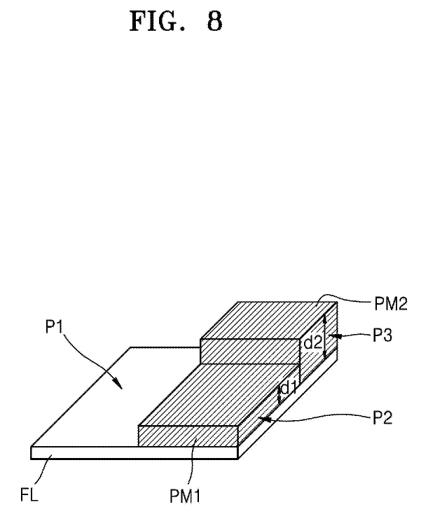

As described above, in case that steps are formed between the first color filter CF1, the second color filter CF2, and the third color filter CF3, respectively, by omitting a black matrix BM between the adjacent color filters CF1, CF2, and CF3 in an emission unit EU, the integration and resolution of the display apparatus 1 and an electronic apparatus including the display apparatus 1 may be improved. This will be described in detail in the method of manufacturing the display apparatus 1 to be described below in FIGS. 8-11.

In the disclosure, the emission unit EU may refer to a pixel unit. For example, the emission unit EU in FIGS. 6 and 7 may include a first subpixel which emits blue light positioned in the first subpixel area P1, a second subpixel which emits red light positioned in the second subpixel area P2, and a third subpixel which emits green light positioned in the third subpixel area P3.

Because the first subpixel, which emits blue light, has lower optical efficiency compared to the second subpixel or the third subpixel even with a same current flowing therethrough, to compensate for the optical efficiency, the emission unit EU of FIGS. 6 and 7 may have the largest area for the first subpixel which emits blue light.

The black matrix BM may be positioned between the emission unit EU and an adjacent different emission unit EU to prevent light leakage or the like. For example, the black matrix BM may be positioned to surround the emission unit EU.

The black matrix BM may include, for example, black resin or metal black. For example, in the same emission unit EU, a black matrix BM may not be positioned between the adjacent color filters CF1, CF2, and CF3.

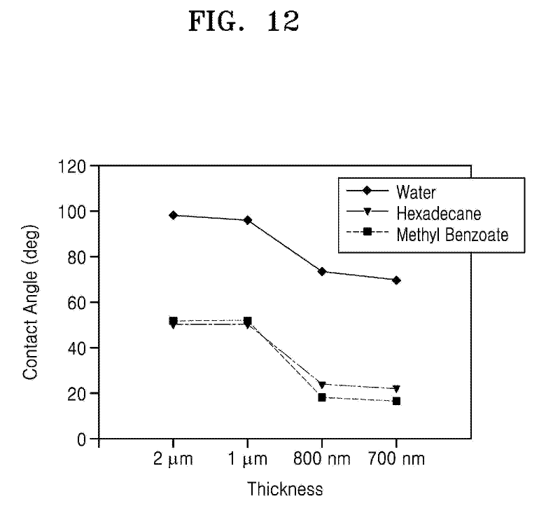

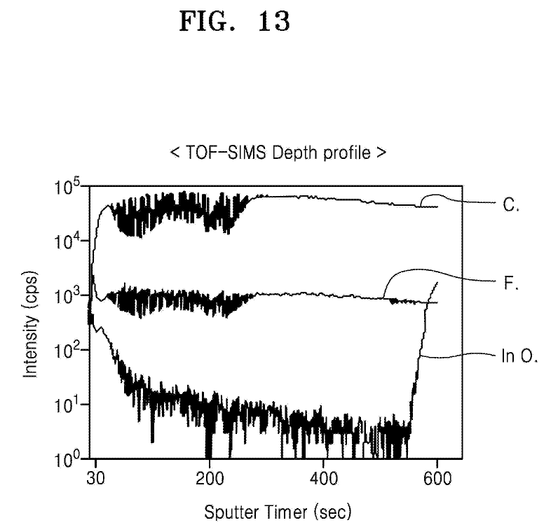

FIGS. 8, 9, 10, and 11 are schematic views of a method of manufacturing the emission unit of FIG. 7. FIG. 12 is a graph illustrating a change in contact angle according to thicknesses of a liquid-repellent material. FIG. 13 is a graph illustrating a time-of-flight secondary ion mass spectrometry (TOF-SIMS) depth profile during a liquid-repellent plasma treatment.

Referring to FIGS. 6-11, the method of manufacturing the display apparatus 1 according to an embodiment of the disclosure may include, on a substrate 100 (see FIG. 5) including a first subpixel area P1, a second subpixel area P2, and a third subpixel area P3, forming a first organic layer PM1 positioned in the second subpixel area P2 and a second organic layer PM2 positioned in the third subpixel area P3, forming, on the substrate 100, a first color filter CF1 positioned in the first subpixel area P1, forming a second color filter CF2 on the first organic layer PM1, and forming a third color filter CF3 on the second organic layer PM2.

Referring to FIG. 8, the first organic layer PM1 positioned in the second subpixel area P2 and the second organic layer PM2 positioned in the third subpixel area P3 may be formed on a functional layer FL on the substrate 100 (see FIG. 5). A thickness d2 of the second organic layer PM2 may be greater than a thickness d1 of the first organic layer PM1.

The first organic layer PM1 and the second organic layer PM2 may be formed through a plurality of photolithography processes. For example, after an organic layer is stacked on the functional layer FL, a first photolithography process may be performed to form the second organic layer PM2. Thereafter, a second photolithography process may be performed to form the first organic layer PM1. However, this is an example, and, in another example, the first organic layer PM1 may be formed on the functional layer FL, and then, the second organic layer Player PM2 stacked on the first organic layer PM1.

The first organic layer PM1 and the second organic layer PM2 may each include an organic insulator, such as a general-purpose polymer including PMMA or PS, a polymer derivative having a phenol-based group, an acrylic polymer, an imide-based polymer, an aryl ether-based polymer, an amide-based polymer, a fluorine-based polymer, a p-xylene-based polymer, a vinyl alcohol-based polymer, or blends thereof.

In some embodiments, the functional layer FL in FIGS. 8-11 is depicted with a smaller thickness than the thickness of the first organic layer PM1 or the second organic layer PM2 on the functional layer FL, but this is for illustrative convenience. In practice, the actual thickness of the functional layer FL in the display apparatus 1 may be greater than the thickness d1 or d2 of the first organic layer PM1 or the second organic layer PM2.

The method of manufacturing the display apparatus 1 according to an embodiment of the disclosure may further include applying a liquid-repellent treatment to the first organic layer PM1 and the second organic layer PM2 during formation of the first organic layer PM1 and the second organic layer PM2. For example, after the first organic layer PM1 and the second organic layer PM2 are formed on the functional layer FL, the first organic layer PM1 and the second organic layer PM2 may each undergo a liquid-repellent treatment such that the first organic layer PM1 and the second organic layer PM2 each may have liquid repellency.

In the disclosure, “liquid repellency” refers to a property of exhibiting a high contact angle with respect to liquids or the like. For example, when the first organic layer PM1 is described as having liquid repellency, it means that the surface of the first organic layer PM1 suppresses the spreading of liquids or the like. Also, it means that the first organic layer PM1 repels liquids or the like.

The first organic layer PM1 or the second organic layer PM2 may undergo a liquid-repellent treatment, for example, by adding a liquid-repellent material. The liquid-repellent material may include, for example, an additive including fluorine or an additive including silicon. For example, the liquid-repellent material may include at least one of Teflon, fluorosilane, polydimethylsiloxane, or fluorinated silicon hybrid.

Referring to FIG. 12, in case that the first organic layer PM1 or the second organic layer PM2 is treated with the aforementioned liquid-repellent material, a contact angle of polar liquid using water, a contact angle of non-polar oil using hexadecane, and a contact angle of medium polarity using methyl benzoate significantly increase when the thickness d1 or d2 of the first organic layer PM1 or the second organic layer PM2 is 1 μm or more.

For example, the liquid repellency of the first organic layer PM1 or the second organic layer PM2 is greatly improved when the thickness d1 or d2 of the first organic layer PM1 or the second organic layer PM2 is 1 μm or more. Accordingly, in case that the first organic layer PM1 is treated with a liquid-repellent material, the thickness d1 of the first organic layer PM1 may be about 1 μm to about 3 μm. For example, as described above, the thickness d2 of the second organic layer PM2 may be greater than the thickness d1 of the first organic layer PM1.

In case that the thickness d1 of the first organic layer PM1 is less than 1 μm, the liquid repellency of the first organic layer PM1 may be reduced, and in case that the thickness d1 of the first organic layer PM1 exceeds 3 μm, waste of materials may be caused and the integration of the display apparatus 1 may be reduced.

Another method of applying a liquid-repellent treatment to the first organic layer PM1 or the second organic layer PM2 may be to plasma-treat the first organic layer PM1 or the second organic layer PM2 with a plasma including fluorine. For example, the first organic layer PM1 or the second organic layer PM2 may be plasma-treated with tetrafluoromethane (CF₄) gas.

Referring to FIG. 13, in case that the first organic layer PM1 or the second organic layer PM2 is plasma-treated with tetrafluoromethane gas, a peak in the intensity of fluorine appears around 30 seconds. In a TOF-SIMS depth profile analysis, a depth etch rate is 2 Å/1 sec. For example, in case that the first organic layer PM1 or the second organic layer PM2 is plasma-treated with tetrafluoromethane gas, fluorine is formed up to about 6 nm or about 7 nm. In case that fluorine is formed on a surface layer of an organic layer, the liquid repellency of the organic layer may be improved.

Therefore, in case that the first organic layer PM1 or the second organic layer PM2 undergoes a liquid-repellent treatment using a plasma including fluorine, the thickness d1 of the first organic layer PM1 may be about 6 nm to about 3 μm. For example, in case that the first organic layer PM1 or the second organic layer PM2 does not undergo a liquid-repellent treatment by adding a liquid-repellent material, but undergoes a liquid-repellent treatment using a plasma including fluorine, the thickness d1 of the first organic layer PM1 and the thickness d2 of the second organic layer PM2 may be reduced, and thus, the integration of the display apparatus 1 and the electronic apparatus including the display apparatus 1 may be improved.

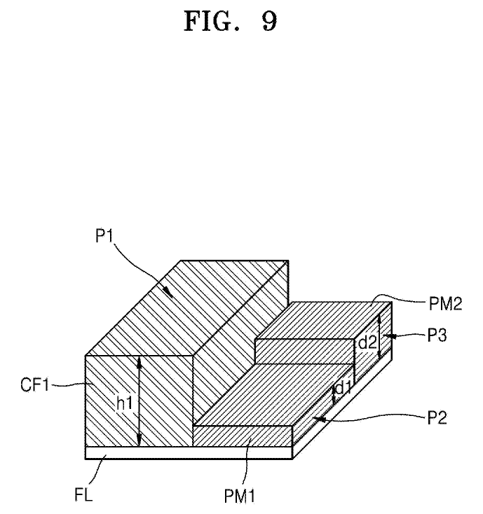

Referring to FIG. 9, the first color filter CF1 positioned in the first subpixel area P1 may be formed on the functional layer FL. For example, the first color filter CF1 may be formed through an inkjet printing process. For example, a thickness h1 of the first color filter CF1 may be greater than the thickness d2 of the second organic layer PM2.

In the disclosure, the thickness h1 of the first color filter CF1, a thickness h2 of the second color filter CF2, and a thickness h3 of the third color filter CF3 may be lengths measured in the third direction z, which is the stacking direction of the display apparatus 1.

As described above, the first organic layer PM1 and the second organic layer PM2 may be subjected to a liquid-repellent treatment, and the functional layer FL, on which the first color filter CF1 is formed, may have a step with the first organic layer PM1 and the second organic layer PM2. For example, a height of the functional layer FL may be lower than heights of the first organic layer PM1 and the second organic layer PM2. Accordingly, during an inkjet printing process for forming the first color filter CF1, the first color filter CF1 may be properly positioned in the first subpixel area P1 on the functional layer FL which is at a relatively lower position. Thus, a black matrix BM surrounding the first subpixel area P1 may be omitted.

In case that, unlike the embodiments of the disclosure, the first organic layer PM1 and the second organic layer PM2 have not undergone a liquid-repellent treatment, and there is no step between the first color filter CF1, the second color filter CF2, and the third color filter CF3, when the black matrix BM surrounding the first subpixel area P1 is omitted and the first color filter CF1 is inkjet-printed in the first subpixel area P1, the first color filter CF1 may also be formed in the adjacent second subpixel area P2 and third subpixel area P3.

For example, in the embodiments of the disclosure, in case that the first organic layer PM1 and the second organic layer PM2 undergo a liquid-repellent treatment, and steps are formed between the functional layer FL on which the first color filter CF1 is formed and each of the first organic layer PM1 and the second organic layer PM2, by omitting the black matrix BM between the adjacent color filters CF1, CF2, and CF3 in the same emission unit EU, the integration and resolution of the display apparatus 1 and the electronic apparatus including the display apparatus 1 may be improved.

In some embodiments, even when the first organic layer PM1 and the second organic layer PM2 undergo a liquid-repellent treatment, and steps are between the functional layer FL on which the first color filter CF1 is formed and each of the first organic layer PM1 and the second organic layer PM2, the first color filter CF1 may also be formed on a portion of the second subpixel area P2 or the third subpixel area P3.

However, as shown in FIG. 7, even when the first color filter CF1 encroaches on (or partially overlaps) a portion of the second subpixel area P2 or the third subpixel area P3 and is formed on a portion of the second subpixel area P2 or the third subpixel area P3, because widths of the second intermediate layer 212-2 and the third intermediate layer 212-3 are smaller than widths of the second color filter CF2 and the third color filter CF3, there is no concern regarding light transmission.

For example, even when the first color filter CF1 encroaches on (or partially overlaps) a portion of the second subpixel area P2 and is formed on a portion of the second subpixel area P2, the first color filter CF1 may not be formed in the overlapping portion SP2 where the second color filter CF2 and the second intermediate layer 212-2 overlap, but may be formed in the non-overlapping portion NSP2 where the second color filter CF2 and the second intermediate layer 212-2 do not overlap. For example, the second color filter CF2 may be positioned in the overlapping portion SP2 where the second color filter CF2 and the second intermediate layer 212-2 overlap. Accordingly, during light emission of the second light-emitting element 200-2, despite the first color filter CF1 positioned in the non-overlapping portion NSP2 where the second color filter filter CF2e second intermediate layer 212-2 do not overlap, light generated from the second light-emitting element 200-2 may properly pass through the second color filter filter CF2oned in the overlapping portion SP2 where the second color filter filter CF2e second intermediate layer 212-2 overlap.

For example, in case that the color filters CF1, CF2, and CF3 include the overlapping portions SP1, SP2, and SP3 and the non-overlapping portions NSP1, NSP2, and NSP3, even when the color filters CF1, CF2, and CF3 partially encroach on (or partially overlap) different areas during an inkjet printing process, light transmission issues may be prevented or minimized.

In some embodiments, the method of manufacturing the display apparatus 1 according to an embodiment of the disclosure may further include applying a liquid-repellent treatment to the first color filter CF1 during formation of the first color filter CF1. The liquid-repellent treatment for the first color filter CF1 may be the same as the liquid-repellent treatment for the first organic layer PM1 or the second organic layer PM2, which includes adding a liquid-repellent material to the first color filter CF1, or plasma-treating the first color filter CF1 with a gas including fluorine. Thus, the first color filter CF may have liquid repellency.

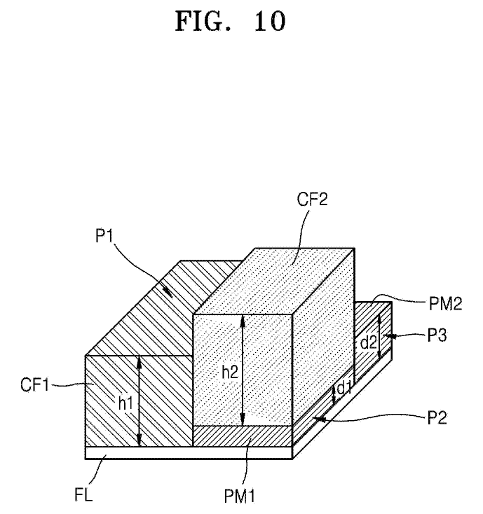

Referring to FIG. 10, the second color filter CF2 may be formed on the first organic layer PM1. For example, the second color filter CF2 may be formed through an inkjet printing process.

As described above, the first organic layer PM1, the second organic layer PM2, and the first color filter CF1 may undergo a liquid-repellent treatment. For example, the first organic layer PM1 on which the second color filter CF2 is formed has a step with the second organic layer PM2 and the first color filter CF1. For example, the height of the first organic layer PM1 may be lower than heights of the second organic layer PM2 and the first color filter CF1. Accordingly, during an inkjet printing process for forming the second color filter CF2, the second color filter CF2 may be properly positioned in the second subpixel area P2 on the first organic layer PM1 which is at a relatively lower position. Thus, the black matrix BM surrounding the second subpixel area P2 may be omitted.

The method of manufacturing the display apparatus 1 according to an embodiment of the disclosure may further include applying a liquid-repellent treatment to the second color filter CF2 during formation of the second color filter CF2. The liquid-repellent treatment for the second color filter CF2 may be the same as the liquid-repellent treatment for the first organic layer PM1 or the second organic layer PM2, which includes adding a liquid-repellent material to the second color filter CF2, or plasma-treating the second color filter CF2 with a gas including fluorine.

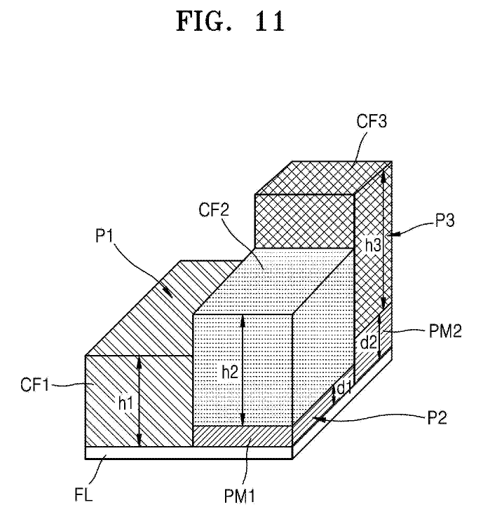

Referring to FIG. 11, the third color filter CF3 may be formed on the second organic layer PM2. For example, the third color filter CF3 may be formed through an inkjet printing process.

As described above, the second organic layer PM2, the first color filter CF1, and the second color filter CF2 may undergo a liquid-repellent treatment. For example, the second organic layer PM2, on which the third color filter CF3 is formed, may have a step with the first color filter CF1 and the second color filter CF2. For example, the height of the second organic layer PM2 may be lower than heights of the first color filter CF1 and the second color filter CF2. Accordingly, during an inkjet printing process for forming the third color filter CF3, the third color filter filter CF3 properly positioned in the third subpixel area P3 on the second organic layer PM2 which is at a relatively lower position. Thus, the black matrix BM surrounding the third subpixel area P3 may be omitted.

In the display apparatus 1 according to an embodiment of the disclosure, the upper surface of the third color filter CF3 may be positioned higher than the upper surface of the second color filter CF2, and the upper surface of the second color filter CF2 may be positioned higher than the upper surface of the first color filter CF1. For example, the thickness d2 of the second organic layer PM2 may be greater than the thickness d1 of the first organic layer PM1, and the thickness h1 of the first color filter CF1 may be greater than the thickness d2 of the second organic layer PM2. In case that the above conditions are satisfied, the thickness h1 of the first color filter CF1, the thickness h2 of the second color filter CF2, and the thickness h3 of the third color filter CF3 may be the same or different.

In some embodiments, as described above, the emission unit EU in FIGS. 6 and 7 may include a first subpixel which emits blue light positioned in the first subpixel area P1, a second subpixel which emits red light positioned in the second subpixel area P2, and a third subpixel which emits green light positioned in the third subpixel area P3. However, the disclosure is not limited thereto, and, in another example, a third subpixel which emits green light may be positioned in the second subpixel area P2 and a second subpixel which emits red light may be positioned in the third subpixel area P3.

Because the first subpixel, which emits blue light, has lower optical efficiency compared to the second subpixel or the third subpixel even with a same current flowing therethrough, to compensate for the optical efficiency, the emission unit EU of FIGS. 6 and 7 may have the largest area for the first subpixel which emits blue light.

Accordingly, during the manufacturing of the display apparatus 1, because the first subpixel has the largest area, the first subpixel which emits blue light, the second subpixel which emits red light, and the third subpixel which emits green light may be manufactured in the order listed. In another example, the first subpixel which emits blue light and has the largest area may be formed first, followed by the third subpixel which emits green light, and then the second subpixel which emits red light. However, the disclosure is not limited thereto, and, in another example, the second subpixel or the third subpixel, which has a relatively smaller area, may be formed before the first subpixel.

In some embodiments, in a comparative example where the black matrix BM is positioned between the adjacent color filters CF1, CF2, and CF3 in the emission unit EU, there has been a concern that an aperture ratio, which is the sum of the areas of apertures of the first subpixel, the second subpixel, and the third subpixel relative to the area of the emission unit EU, may decrease. However, in case that the black matrix BM is omitted, the aperture ratio, which is the sum of the areas of the apertures of the first subpixel, the second subpixel, and the third subpixel relative to the area of the emission unit EU, may increase.

For example, in the case of the display apparatus 1 with a resolution of 282 pixels per inch (ppi), an aperture ratio of a display apparatus 1 in the comparative example is 0.502, but an aperture ratio of the display apparatus 1 according to the embodiment may be 0.590. For example, in the case of the display apparatus 1 with a resolution of 424 ppi, the aperture ratio of the display apparatus 1 in the comparative example is 0.308, but the aperture ratio of the display apparatus 1 according to the embodiment may be 0.412. For example, in the case of the display apparatus 1 with a resolution of 564 ppi, the aperture ratio of the display apparatus 1 in the comparative example is 0.153, but the aperture ratio of the display apparatus 1 according to the embodiment may be 0.266.

For example, the aperture ratio of the display apparatus 1 according to an embodiment of the disclosure may increase by about 15 % to about 75 % compared to the aperture ratio of the display apparatus 1 in the comparative example. Accordingly, the integration and resolution of the display apparatus 1 and the electronic apparatus including the display apparatus 1 may be improved.

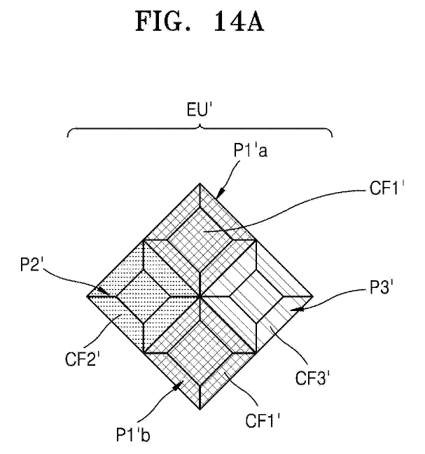

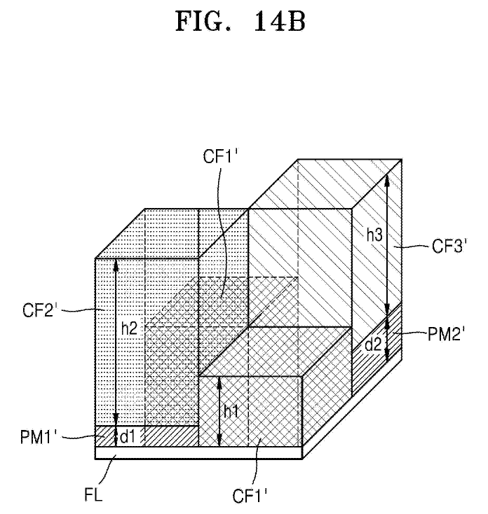

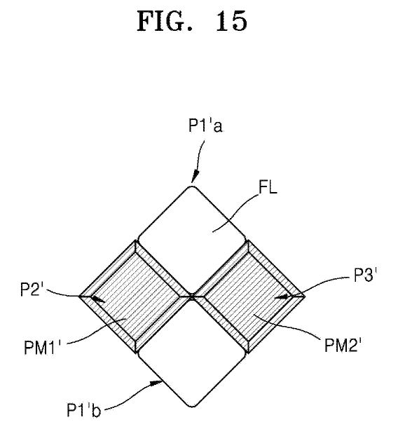

FIGS. 14A and 14B are schematic view of an emission unit of the display apparatus of FIG. 1, according to another embodiment, and FIGS. 15-17 are schematic cross-sectional views illustrating a method of manufacturing the emission unit of FIGS. 14A and 14B.

The configuration below an emission unit EU’ of FIGS. 14A, 14B, 15, 16, and 17 is the same as the configuration described above in FIGS. 6-11, and thus, the redundant explanation is omitted.

Referring to FIGS. 14A, 14B, 15, 16, and 17, the light-emitting element structure 200 (see FIG. 7) of the display apparatus 1 (see FIG. 1) according to another embodiment of the disclosure may include an emission unit EU’ including two first light-emitting elements 200-1, one second light-emitting element 200-2, and one third light-emitting elements 200-3. For example, in the emission unit EU’, the second light-emitting element 200-2 and the third light-emitting element 200-3 may face each other, and the two first light-emitting elements 200-1 may face each other between the second light-emitting element 200-2 and the third light-emitting element elements 200-3o first light-emitting elementelements 200-1 disposed opposite each other in a first diagonal direction, and may be positioned between the second light-emitting element 200-2 and the third light-emitting element elements 200-3cond diagonal direction intersecting the first diagonal direction. The emission unit EU’ may also be referred to as a diamond-shaped PenTile^{TM} structure.

The first light-emitting element 200-1 of the emission unit EU’ may be positioned on the substrate 100 (see FIG. 5) in first subpixel areas P1a’ and P1b’ and may emit green light. For example, the second light-emitting element 200-2 may be positioned on the substrate 100 in the second subpixel area P2’ and may emit blue light. For example, the third light-emitting elements 200-3 may be positioned on the substrasubstrate 100hird subpixel area P3’ and may emit red light.

A first color filter CF1’ may be positioned on the first light-emitting element 200-1, a second color filter CF2’ may be positioned on the second light-emitting element 200-2, and a third color filter CF3’ may be positioned on the third light-emitting elements 200-3. For example, the functional layer FL may be positioned between the light-emitting element structure 200 and the first color filter CF1’, the second color filter CF2’, and the third color filter CF3’.

The first color filter CF1’ may transmit light of a same wavelength as the light emitted from the first light-emitting element 200-1. For example, the second color filter CF2’ may transmit light of a same wavelength as the light emitted from the second light-emitting element 200-2. For example, the third color filter CF3’ may transmit light of a same wavelength as the light emitted from the third light-emitting elements 200-3.

The display apparatus 1 according to another embodiment of the disclosure may further include a first organic layer PM1’ positioned between the second color filter CF2’ and the functional layer FL, and a second organic layer PM2’ positioned between the third color filter CF3’ and the functional layer FL. For example, the first color filter CF1’ may be positioned (e.g., positioned directly) on the functional layer FL, the second color filter CF2’ may be positioned on the first organic layer PM1’ on the functional layer FL, and the third color filter CF3’ may be positioned on the second organic layer PM2’ on the functional layer FL. Referring to FIG. 14B, a thickness d1 of the first organic layer PM1’ and a thickness d2 of the second organic layer Player PM2e the same as each other.

For example, a step may be formed between the first color filter CF1’ and the second color filter CF2’, and another step may be formed between the first color filter CF1’ and the third color filter CF3’. For example, an upper surface of the first color filter CF1’ may be positioned lower than an upper surface of the second color filter CF2’, and the upper surface of the second color filter CF2’ and an upper surface of the third color filter CF3’ may be positioned at a same level. See, e.g., FIG. 14B.

The method of manufacturing the display apparatus 1 according to another embodiment of the disclosure may include, on the substrate 100 (see FIG. 5) including the first subpixel areas P1a’ and P1b’, the second subpixel area P2’, and the third subpixel area P3’, forming the first organic layer PM1’ positioned in the second subpixel area P2’ and the second organic layer PM2’ positioned in the third subpixel area P3’, forming, on the substrate 100, the first color filter CF1’ positioned in the first subpixel areas P1a’ and P1b’, forming the second color filter CF2’ on the first organic layer PM1’, and forming the third color filter CF3’ on the second organic layer PM2’.

Referring to FIG. 15, the first organic layer PM1’ positioned in the second subpixel area P2’ and the second organic layer PM2’ positioned in the third subpixel area P3’ may be formed on the functional layer FL on the substrate 100. The thickness of the second organic layer PM2’ may be the same as the thickness of the first organic layer PM1’.

The first organic layer PM1’ and the second organic layer PM2’ may be formed through a single photolithography process. For example, after an organic layer is stacked on the functional layer FL, a photolithography process may be performed to form the first organic layer PM1’ and the second organic layer PM2’ having a same height.

The first organic layer PM1’ and the second organic layer PM2’ may each include an organic insulator, such as a general-purpose polymer including PMMA or PS, a polymer derivative having a phenol-based group, an acrylic polymer, an imide-based polymer, an aryl ether-based polymer, an amide-based polymer, a fluorine-based polymer, a p-xylene-based polymer, a vinyl alcohol-based polymer, or blends thereof.

The method of manufacturing the display apparatus 1 according to another embodiment of the disclosure may further include applying a liquid-repellent treatment to the first organic layer PM1’ and the second organic layer PM2’ during formation of the first organic layer PM1’ and the second organic layer PM2’. For example, after the first organic layer PM1’ and the second organic layer PM2’ are formed on the functional layer FL, the first organic layer PM1’ and the second organic layer PM2’ may each undergo a liquid-repellent treatment such that the first organic layer PM1’ and the second organic layer PM2’ each have liquid repellency.

The liquid-repellent treatment for the first organic layer PM1’ and the second organic layer PM2’ may include addition of a liquid-repellent material or plasma treatment using a gas including fluorine.

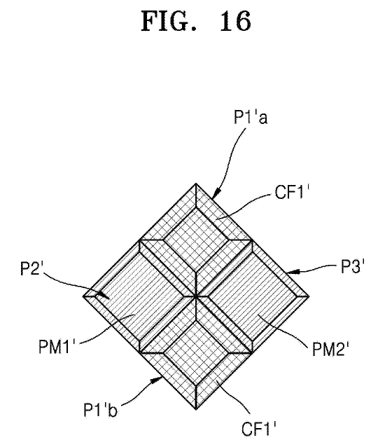

Referring to FIG. 16, a first color filter CF1’ positioned in the first subpixel areas P1a’ and P1b’ may be formed on the functional layer FL. For example, the first color filter CF1’ may be formed through an inkjet printing process. For example, a thickness of the first color filter CF1’ may be greater than the thickness d2 of the first organic layer PM1’ and the second organic layer PM2’.

As described above, the first organic layer PM1’ and the second organic layer PM2’ may undergo a liquid-repellent treatment, and the functional layer FL on which the first color filter CF1’ is formed has a step with the first organic layer PM1’ and the second organic layer PM2’. For example, the height of the functional layer FL may be lower than heights of the first organic layer PM1’ and the second organic layer PM2’. Accordingly, during an inkjet printing process for forming the first color filter CF1’, the first color filter CF1’ may be properly positioned in the first subpixel areas P1a’ and P1b’ on the functional layer FL which is at a relatively lower position. Thus, the black matrix BM (see FIG. 6) surrounding the first subpixel areas P1a’ and P1b’ may be omitted.

The method of manufacturing the display apparatus 1 according to another embodiment of the disclosure may further include applying a liquid-repellent treatment to the first color filter CF1’ during formation of the first color filter CF1’. The liquid-repellent treatment for the first color filter CF1’ may be the same as the liquid-repellent treatment for the first organic layer PM1’ or the second organic layer PM2’, which includes adding a liquid-repellent material to the first color filter CF1’, or plasma-treating the first color filter CF1’ with a gas including fluorine.

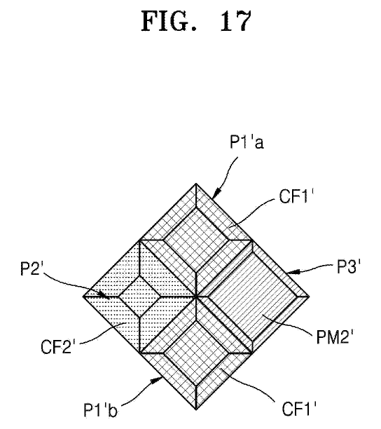

Referring to FIG. 17, the second color filter CF2’ may be formed on the first organic layer PM1’. For example, the second color filter CF2’ may be formed through an inkjet printing process.

As described above, the first color filter CF1’ may undergo a liquid-repellent treatment. For example, the first organic layer PM1’ on which the second color filter CF2’ is formed is positioned between the first color filters CF1’ which have a higher height. Accordingly, during an inkjet printing process for forming the second color filter CF2’, the second color filter CF2’ may be properly positioned in the second subpixel area P2’ on the first organic layer PM1’ which is at a relatively lower position. For example, the black matrix BM surrounding the second subpixel area P2’ may be omitted.

Referring to FIGS. 14A and 14B, the third color filter CF3’ may be formed on the second organic layer PM2’. For example, the third color filter CF3’ may be formed through inkjet printing.

As described above, the first color filter CF1’ may undergo a liquid-repellent treatment. For example, the second organic layer PM2’ on which the third color filter CF3’ is formed is positioned between the first color filters CF1’ which have a higher height. Accordingly, during inkjet printing for forming the third color filter CF3’, the third color filter CF3’ may be properly positioned in the third subpixel area P3’ on the second organic layer PM2’ which is at a relatively lower position. For example, the black matrix BM surrounding the third subpixel area P3’ may be omitted.

According to the embodiments of the disclosure, by omitting a black matrix BM between the adjacent color filters CF1’, CF2’, and CF3’ in the emission unit EU’, the integration and resolution of the display apparatus 1 and the electronic apparatus including the display apparatus 1 may be improved.

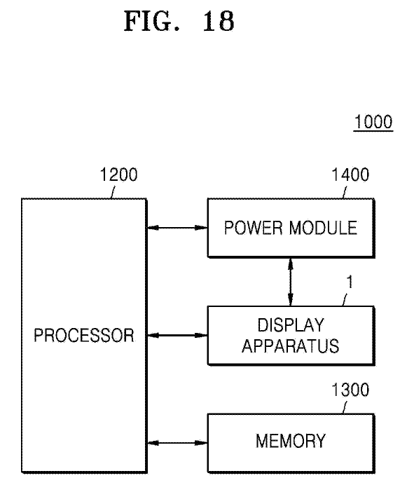

FIG. 18 is a block diagram of an electronic apparatus according to an embodiment.

Referring to FIG. 18, an electronic apparatus 1000 according to an embodiment may include a display apparatus 1, a processor 1200, a memory 1300, and a power supply 1400.

The display apparatus 1 may receive data from the processor 1200 and provide visual information. The display apparatus 1 may be the display apparatus 1 according to the embodiments of the disclosure described above.

The processor 1200 may include at least one of a central processing unit (CPU), an application processor (AP), a graphics processing unit (GPU), a communication processor (CP), and an image signal processor (ISP). For example, the processor 1200 may operate by executing at least one program.

A memory 1300 may store data information necessary for the operation of the processor 1200 or the display apparatus 1. For example, the memory 1300 may store the at least one program. In case that the processor 1200 executes an application stored in the memory 1300, an image data signal and/or an input control signal may be transmitted to the display apparatus 1, and the display apparatus 1 may process the received signals to output image information through a display screen.

The power supply 1400 may include a power supply module, such as a power adapter or a battery apparatus, and a power conversion module which generates power necessary for the operation of the electronic apparatus 1000 by converting power supplied by the power supply module. For example, the power supply 1400 may supply power to the display apparatus 1.

At least one of the components of the electronic apparatus 1000 described above may be included in the display apparatus 1 according to the embodiments described above. For example, some of individual modules included in one module functionally may be included in the display apparatus 1, and other modules may be provided separately from the display apparatus 1.

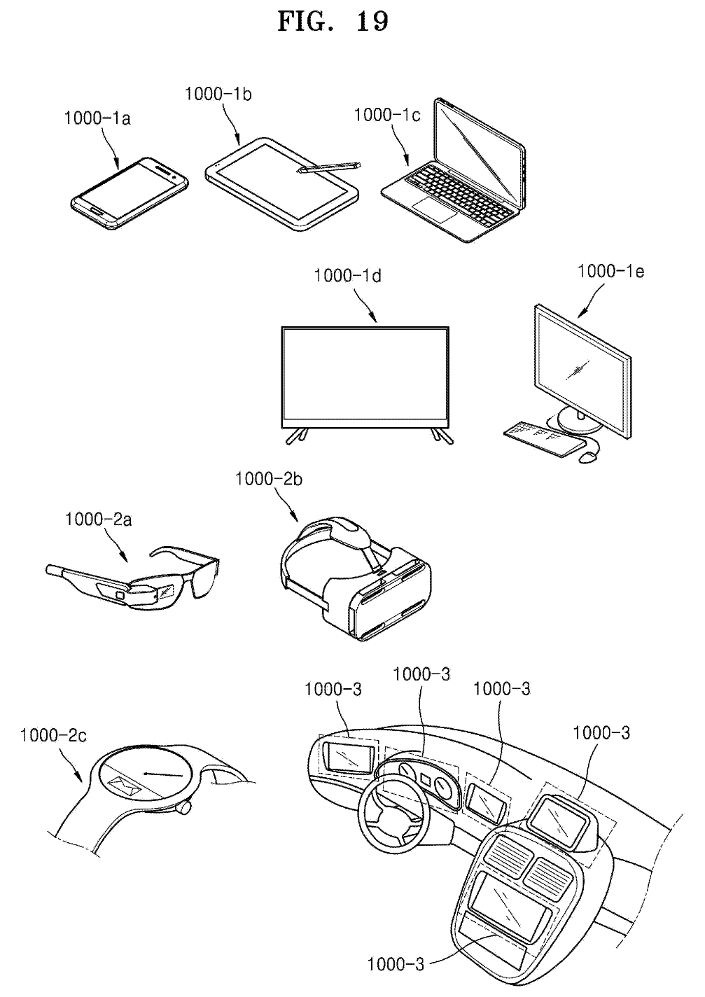

FIG. 19 illustrates schematic diagrams of electronic apparatuses according to various embodiments.

Referring to FIG. 19, various electronic apparatuses, to which the display apparatus according to the embodiments of the disclosure is applied, may include not only an electronic apparatus for displaying images, such as a smartphone 1000-1a, a tablet personal computer (PC) 1000-1b, a laptop computer 1000-1c, a television (TV) 1000-1d, or a desktop monitor 1000-1e, but also a wearable electronic apparatus including a display apparatus, such as smart glasses 1000-2a, a head-mounted display (HMD) 1000-2b, or a smart watch 1000-2c, and vehicle electronic apparatuses 1000-3 including a display apparatus, such as a center information display (CID) positioned on an instrument panel, a center fascia, a dashboard of a vehicle, or a room mirror display.

According to the embodiments of the disclosure, by omitting a black matrix between adjacent color filters in an emission unit, the integration and resolution of a display apparatus and an electronic apparatus including the display apparatus may be improved.

However, the effects that may be obtained through the disclosure are not limited to the effects described above, and other technical effects not mentioned may be clearly understood by those of ordinary skill in the art from the description of the disclosure above.

The embodiments described above may be embodiments that may be implemented independently, but the structure of each embodiment may be applied in combination to other embodiments.

As described above, the disclosure has been described with reference to the one or more embodiments shown in the accompanying drawings, but should be considered in a descriptive sense only. Those of ordinary skill in the art will understand that various modifications and equivalent embodiments may be made therefrom. Therefore, the true technical scope of the disclosure should be defined by the technical spirit of the appended claims.

Specific implementations described in the embodiments are only embodiments, and do not limit the scope of the embodiments by any means. For example, unless specifically described as “essential” or “significant”, the components described in the embodiments should not be considered as required for the application of the disclosure.

The use of the term “the” and similar referential terms in the disclosure of the embodiments (especially in the claims) may apply to both singular and plural forms.

For example, when a range is stated in the embodiments, the disclosure encompasses inventions applied with any individual value within that range (unless stated otherwise), equivalent to explicitly listing each individual value constituting the range in the detailed description.

Finally, the operations constituting the method according to the embodiments may be performed in any appropriate order, unless the sequence is explicitly specified or otherwise indicated as critical. The embodiments are not limited to the stated order of the operations.

In the embodiments, the use of all examples or exemplary terms is simply to describe the embodiments in detail, and unless limited by the claims, the scope of the embodiments is not limited by the examples or exemplary terms.

Those of ordinary skill in the art will appreciate that various modifications, combinations, and changes may be configured according to design conditions and factors within the scope of the appended claims or equivalents thereof.

What is claimed is:

1. A display apparatus comprising:
a substrate comprising a first subpixel area and a second subpixel area;
a light-emitting element structure comprising a first light-emitting element on the substrate in the first subpixel area and a second light-emitting element on the substrate in the second subpixel area;
a color filter structure comprising a first color filter on the first light-emitting element and a second color filter on the second light-emitting element; and
a functional layer between the light-emitting element structure and the color filter structure,
wherein an upper surface of the first color filter is lower than an upper surface of the second color filter.

2. The display apparatus of claim 1, wherein the light-emitting element structure further comprises a third light-emitting element on the substrate in a third subpixel area,
wherein the color filter structure further comprises a third color filter on the third light-emitting element, and
wherein the display apparatus further comprises a first organic layer between the second color filter and the functional layer and a second organic layer between the third color filter and the functional layer.

3. The display apparatus of claim 2, wherein a thickness of the second organic layer is greater than a thickness of the first organic layer.

4. The display apparatus of claim 3, wherein a thickness of the first color filter is greater than the thickness of the second organic layer.

5. The display apparatus of claim 2, wherein a thickness of the first organic layer is in a range of 1 μm to 3 μm.

6. The display apparatus of claim 2, wherein the first organic layer and the second organic layer have liquid repellency.

7. The display apparatus of claim 6, wherein the first color filter and the second color filter have liquid repellency.

8. The display apparatus of claim 2, wherein the first organic layer and the second organic layer have a same thickness.

9. The display apparatus of claim 8, wherein the first color filter has liquid repellency.

10. The display apparatus of claim 8, wherein the light-emitting element structure comprises an emission unit comprising two first light-emitting elements, one second light-emitting element, and one third light-emitting element,
wherein in the emission unit, the second light-emitting element and the third light-emitting element face each other, and
wherein the two first light-emitting elements face each other in a first diagonal direction and are between the second light-emitting element and the third light-emitting element in a second diagonal direction.

11. A method of manufacturing a display apparatus, the method comprising:
on a substrate comprising a first subpixel area, a second subpixel area, and a third subpixel area, forming a first organic layer in the second subpixel area and a second organic layer in the third subpixel area;
forming, on the substrate, a first color filter in the first subpixel area;
forming a second color filter on the first organic layer; and
forming a third color filter on the second organic layer,
wherein an upper surface of the first color filter is lower than an upper surface of the second color filter.

12. The method of claim 11, further comprising:
during formation of the first organic layer and the second organic layer,
applying a liquid-repellent treatment to the first organic layer and the second organic layer.

13. The method of claim 12, further comprising:
during formation of the first color filter, applying a liquid-repellent treatment to the first color filter.

14. The method of claim 13, further comprising:
during formation of the second color filter, applying a liquid-repellent treatment to the second color filter.

15. The method of claim 11, wherein a thickness of the second organic layer is greater than a thickness of the first organic layer.

16. The method of claim 15, wherein a thickness of the first color filter is greater than the thickness of the second organic layer.

17. The method of claim 16, wherein an upper surface of the third color filter is higher than the upper surface of the second color filter.

18. The method of claim 11, wherein the first organic layer and the second organic layer have a same thickness.

19. The method of claim 18, wherein an upper surface of the third color filter and an upper surface of the second color filter are at a same level .

20. An electronic apparatus comprising:
a memory configured to store at least one program;
a processor configured to execute the at least one program;
a display apparatus configured to receive data from the processor and provide visual information; and
a power supply configured to supply power to the display apparatus,
wherein the display apparatus comprises:
a substrate comprising a first subpixel area and a second subpixel area;
a light-emitting element structure comprising a first light-emitting element on the substrate in the first subpixel area and a second light-emitting element on the substrate in the second subpixel area;
a color filter structure comprising a first color filter on the first light-emitting element and a second color filter on the second light-emitting element; and
a functional layer between the light-emitting element structure and the color filter structure, and
wherein an upper surface of the first color filter is lower than an upper surface of the second color filter.
